(19) United States
(12) Patent Application Publication
(10) Pub. No.: US 2008/0278181 A1
(43) Pub. Date: Nov. 13, 2008

(54) OXIDATION-RESISTANT, LIGAND-CAPPED COPPER NANOPARTICLES AND METHODS FOR FABRICATING THEM

(75) Inventors: Chuan-Jian ZHONG, Endwell, NY (US); Derrick MOTT, Vestal, NY (US)

Correspondence Address: NIXON PEABODY LLP - PATENT GROUP, 1100 CLINTON SQUARE, ROCHESTER, NY, 14604, US

(73) Assignee: Research Foundation of State University of New York, Binghamton, NY (US)

(21) Appl. No.: 12/044,552

(22) Filed: Mar. 7, 2008

Related U.S. Application Data
(60) Provisional application No. 60/893,481, filed on Mar. 7, 2007.

(51) Int. Cl. G01R 27/22; B32B 5/16; B05D 3/00; C09D 11/02; B05D 5/00

(52) U.S. Cl. 324/693; 428/403; 427/217; 106/31.13; 427/256; 106/287.18; 428/328

(57) ABSTRACT

The present invention is directed toward oxidation-resistant, ligand-capped nanoparticles, each comprising one or more capping ligands on a copper-containing core. Methods of making and using these nanoparticles are also disclosed.

The present application claims benefit of U.S. Provisional Application Ser. No. 60/893,481, filed Mar. 7, 2007, which is hereby incorporated by reference in its entirety.

The subject matter of this application was made with support from the United States Government under National Science Foundation, Grant No. CHE 0349040 and the Air Force Office of Scientific Research, Grant No. FA8650-07-2-6836. The U.S. Government has certain rights in this invention.

### FIELD OF THE INVENTION

The present invention relates to oxidation-resistant, ligand-capped nanoparticles, each comprising one or more capping ligands on a copper-containing core and methods for fabricating them.

### BACKGROUND OF THE INVENTION

The ability to synthesize nanoparticles of different composition with desired sizes and shapes is important in exploring the applications in catalysis, sensors, microelectronics, and many other areas of nanotechnology See Hoover, N., et al., J. Phys. Chem. B, 110: 8606 (2006) and Niu, Y., et al., Chem. Mater., 15: 3463 (2003). The nanoscale properties of copper and its alloys have found applications in catalysis, e.g. water-gas-shift catalysts and gas detoxification catalysts. See Vukojevic, S., et al., Angew. Chem. Int. Ed., 44: 7978-7981 (2005) and Barrabes, N., et al., Applied Catalysis B., 62: 77-85 (2006). The synthesis of copper nanoparticles with controllable size, shape, and surface properties is vital to exploring copper-based catalysis. See Hoover, N., et al., J. Phys. Chem. B, 110: 8606 (2006) and Niu, Y., et al., Chem. Mater., 15: 3463 (2003). Such abilities will also lead to an increased use of copper in many other areas of nanotechnology that are currently dominated by use of gold, silver, and platinum nanoparticles. While there are a number of approaches to synthesizing copper nanoparticles under specific conditions, few methods have been established to control size and shape effectively. See Dhas, N., et al., Chem. Mater., 10: 1446-1452 (1998) and Zhul, H., et al., Nanotechnology, 16: 3079-3083 (2005). Due to the propensity of surface oxidation of copper (see Chen, S., et al., J. Pys. Chem. B, 105: 8816 (2001)), a key question that must be addressed is: can copper nanoparticles be produced with controllable sizes and shapes? To date, attempts have had relatively limited success in synthesizing copper nanoparticles with controllable size, shape, and surface properties. In previous reports, copper nanoparticles have been synthesized using methods that include organic encapsulation in aqueous phase (see Kim, Y. H., et al., Mol. Cryst. Liq. Cryst., 445: 231 (2006)), encapsulation of copper in thiol capping agent (see Chen, S., et al., J. Pys. Chem. B, 105: 8816 (2001)), and thermal decomposition. See Sun, S., et al., Transactions on Magnets, 37: 4 (2001) and Sun, S., et al., Science, 287: 1989 (2000). The copper nanoparticles that resulted from these methods have either poor monodispersity in size or were susceptible to oxidation. See Dhas, N., et al., Chem. Mater., 10: 1446-1452 (1998); Zhul, H., et al., Nanotechnology, 16: 3079-3083 (2005); and Chen, S., et al., J. Pys. Chem. B, 105: 8816 (2001).

Recently, the chemical reduction of copper ions in mixed reverse micelles (using AOT surfactant (bis(2-ethylhexyl)sulfosuccinate) in water/isooctane) was reported by Pileni and co-workers to produce copper nanocrystals with different shapes. See Salzemann, C., et al., Langmuir, 20: 11772-11777 (2004). The nanoparticle shape was found to depend on the concentration of reducing agents, with spherical shapes formed in lower concentrations and other shapes such as pentagons, cubes, tetrahedra, and elongated forms in higher concentrations. The formation of some initial seed shapes and difference of the relative rates of growth on different crystal facets were proposed to explain the shape formation. The understanding of how different control parameters are operative mechanistically is, therefore, quite elusive.

The interparticle physical or chemical properties of molecularly-capped nanoparticles have been explored for chemical sensing in a number of significant ways. See Templeton, A., et al., Acc. Chem. Res., 33: 27 (2000); Daniel, M., et al., Chem. Rev., 104: 293 (2004); Zhong, C., et al., Nanoparticle Assemblies and Superstructure Ed. by N. Kotov, Marcel Decker Publishers (2005); Wohltjen, H., et al., Anal. Chem., 70: 2856 (1998); Evans, S., et al., J. Mater. Chem., 10: 183 (2000); Severin, E., et al., Anal Chem., 72: 2008 (2000); Shinar, R., et al., Anal. Chem., 72: 5981 (2000); Han, L., et al., Anal. Chem., 73: 4441 (2001); Houser, E., et al., Talanta, 54: 469 (2001); Zamborini, F., et al., J. Am. Chem. Soc., 124: 8958 (2002); Zamborini F., et al., Anal. Chim. Acta, 496: 3 (2003); Cai, Q., et al., Anal Chem., 74: 3533 (2002); Grate, J., et al., Anal Chem., 75: 1868 (2003); Grate, J., et al., Anal. Chem., 75: 1868 (2003); Joseph, Y., et al., J. Phys. Chem. B, 107: 7406 (2003); Joseph, Y., et al., Faraday Discuss., 125: 77 (2004); and Joseph, Y., et al., Sens. Actuators B., 98: 188 (2004). Development of additional sensing techniques remains an objective for those skilled in the art.

The present invention is directed to overcoming these and other deficiencies in the art.

### SUMMARY OF THE INVENTION

One aspect of the present invention is directed toward oxidation-resistant, ligand-capped nanoparticles, each comprising one or more capping ligands on a copper-containing core.

Another aspect is directed to a method of making oxidation-resistant, ligand-capped nanoparticles comprising one or more capping ligands on a copper-containing core. This method includes providing copper-containing core precursor material and a reducing agent. The core precursor material is treated with the reducing agent. Then, one or more capping ligand precursors are provided to be contacted with the reducing agent-treated copper-containing core precursor material under conditions effective to form oxidation-resistant, ligand-capped nanoparticles comprising one or more capping ligands on a copper-containing core.

A further aspect of the present invention is directed toward an ink composition comprising oxidation-resistant, ligand-capped nanoparticles, each comprising one or more capping ligands on a copper-containing core.

Another aspect of the present invention is directed toward a method of printing comprising printing an ink composition comprising oxidation-resistant, ligand-capped nanoparticles, each comprising one or more capping ligands on a copper-containing core onto a substrate.

Yet another aspect of the present invention is directed toward a thin film comprising a plurality of oxidation-resistant, ligand-capped nanoparticles, each comprising one or more capping ligands on a copper-containing core operably linked together in the form of a thin film.

A still further aspect of the present invention is directed toward a detector for volatile organic compounds comprising a sensing platform comprising the thin film of the present invention assembled on a chemiresistor device. This detector also includes a resistance measurement meter connected to a voltage source.

Yet another aspect of the present invention is directed toward a method of detecting volatile organic compounds including providing a detector substantially the same as described above and analyzing a sample with the detector to detect the presence of volatile organic compounds in the sample.

The present invention describes an effective route for the synthesis of copper nanoparticles with controlled sizes and shapes by a combination of controlled reaction temperature and capping agent. See FIG. 1. This route takes advantage of the possible effect of particle sizes on the melting temperature of copper nanoparticles under the reaction conditions. This route to the synthesis of copper nanoparticles not only allows nanoparticles of controllable sizes, but also produces shaped nanoparticles, including rods and cubes. Such abilities have important implications to engineering sizes and shapes of copper-based nanoparticles of different compositions for useful applications, e.g. in catalytic reactions. See Zhong, C. J., et al., in Nanotechnology in Catalysis, Ed. By B. Zhou, et al., Kluwer Academic/Plenum Publishers. Vol. 1., Chapter 11, pp. 222-248 (2004), which is hereby incorporated by reference in its entirety.

A new route for the synthesis of copper nanoparticles in organic suspension has been demonstrated. The size, shape, and stability of the nanoparticles are highly dependent on the reaction temperature, with the size of copper nanoparticles increasing with the reaction temperature in an approximately linear manner. On the basis of theoretical consideration of the size dependence of the melting temperature of copper nanoparticles, it is believed that the surface melting of the nanoparticles is responsible for the interparticle coalescence, leading to the size growth as the reaction temperature is increased. This temperature-controlled size growth is the first example demonstrating the important role of surface melting in the synthesis of copper nanoparticles. The feasibility of synthesizing copper nanoparticles with well-defined shapes such as rods and cubes has also been demonstrated. Mechanistically, the shape formation is linked to a combination of the initial formation of a seed precursor and the preferential adsorption of capping agents on selected nanocrystal facets in order to kinetically control the growth rates of certain crystal facets.

The viability of synthesizing size- and shape-controlled copper nanoparticles is extremely exciting, which constitutes an important area of continued research. By controlling the synthetic parameters, the synthesis of monodispersed copper nanoparticles with the desired shapes such as cubes or rods can be achieved. Systematic experiments are underway to determine the correlation between the control parameters and the seeding/growth parameters. Insights into this correlation will have important implications in the design and engineering of metal nanoparticles of desired sizes and shapes as building blocks in constructing functional materials for applications in many areas of nanotechnology, including catalysis and chemical sensing.

### BRIEF DESCRIPTION OF THE DRAWINGS

FIG. 1 is a schematic drawing illustrating the synthesis for oxidation-resistant, ligand-capped nanoparticles. Component 1A represents copper-containing core precursor material. Component 1B represents the reaction steps of combining the precursor material with a reducing agent and then adding capping agents to produce component 1C. Component 1C represents an oxidation-resistant, ligand-capped nanoparticle having capping ligands on a copper-containing core. Component 1D is a representation of detail of component 1C.

FIGS. 2A-B show solutions of Cu nanoparticles synthesized at 150° C. (FIG. 2A) and 180° C. (FIG. 2B). A green laser beam was shined into the solution which produces the observed light scattering due to the presence of nanoparticles in the solutions.

FIG. 3A-C show Transmission Electron Microscopy (TEM) micrographs. FIG. 3A shows a micrograph of Cu nanoparticles synthesized at 150° C. FIG. 3B shows a micrograph of Cu nanoparticles synthesized at 160° C. FIG. 3C shows a micrograph of Cu nanoparticles synthesized at 190° C.

FIG. 4 is a graph of nanoparticle size vs. synthesis temperature up to 190° C. The line represents the linear regression of the data.

FIG. 5 shows a graph of theoretical modeling of the melting temperature of copper nanoparticles as a function of particle radius based on equation 1. The parameters used for the theoretical calculation were ρₛ=8960 and ρₗ=8020 kg/m², L=20500 J/Kg [15], and γₛ=1.29 and γₗ=1.11 J/m². The actual temperatures used in the synthesis vs. the particle size are included as square points.

FIG. 6 shows a TEM micrograph of copper nanoparticles synthesized at 210° C. FIGS. 6B-D show enlarged views of cube (FIG. 6B), tetraheda (FIG. 6C), and rod (FIG. 6D) shaped particles.

FIG. 7 shows a plot of an X-ray Diffraction (XRD) pattern of the copper nanoparticles synthesized at 210° C.

FIGS. 8A-B show sensor response profiles (FIG. 8A) and a response sensitivity plot (FIG. 8B) to benzene (Bz) vapor for a thin film assembly of Cu nanoparticles (NDT-Cu) on an interdigitated microelectrode (IME) device.

FIG. 9 is a schematic drawing illustrating the design of a sensor device where the nanoparticle thin films on interdigitated microelectrodes are exposed to volatile organic compounds and the change in resistance is measured.

### DETAILED DESCRIPTION OF THE INVENTION

One aspect of the present invention is directed toward oxidation-resistant, ligand-capped nanoparticles, each comprising one or more capping ligands on a copper-containing core The nanoparticles may be present in a monodispersion and may have a particle size between 2-55 nm. The nanoparticles may be cube-shaped, rod-shaped, tetrahedron-shaped, or spherical. Oxidation-resistant, ligand-capped copper nanoparticles remain stable under ambient conditions. By oxidation-resistant, one of ordinary skill in the art will understand that the nanoparticles will remain stable and unchanged for extended periods of time under ambient conditions (e.g. in air at standard temperature and pressure).

The one or more capping ligands may be oleic acid, oleyl amine, and mixtures thereof. Where the one or more capping ligands is a mixture of oleic acid and oleyl amine, the ratio of oleic acid to oleyl amine may be from 1:99 to 99:1 and may be equimolar.

Another aspect is directed to a method of making oxidation-resistant, ligand-capped nanoparticles comprising one or more capping ligands on a copper-containing core. This method includes providing copper-containing core precursor material and a reducing agent. The core precursor material is treated with the reducing agent. Then, one or more capping ligand precursors are provided to be contacted with the reducing agent-treated copper-containing core precursor material under conditions effective to form oxidation-resistant, ligand-capped nanoparticles comprising one or more capping ligands on a copper-containing core.

The copper-containing core precursor material may be copper (II) acetyl acetonate. The reducing agent may be 1,2 hexadecanediol. The specific materials and ratios used to form these oxidation-resistant, ligand-capped nanoparticles comprising one or more capping ligands on a copper-containing core as well as the sizes, shapes, and structures of the nanoparticles themselves are substantially the same as those described above.

The reaction conditions may include combining the copper-containing core precursor and the reducing agent and heating them to a first temperature to produce a heated reaction mixture. The first temperature may be 100 to 110° C. The heated reaction mixture may be further combined with one or more capping ligand precursors and heated to a second temperature under conditions effective to form the oxidation resistant, ligand-capped nanoparticles comprising one or more capping ligands on a copper-containing core. The second temperature may be 145 to 210° C.

Examples of different size nanoparticles produced by controlled temperatures are as follows:

| Temperature range | Approximate size range |
|---|---|
| 145-155° C. | 3-7 nm |
| 150 to 165° C. | 6-12 nm |
| 165 to 175° C. | 12-17 nm |
| 176 to 185° C. | 13-18 nm |
| 186 to 210° C. | 16-32 nm |

A further aspect of the present invention is directed toward an ink composition comprising oxidation-resistant, ligand-capped nanoparticles, each comprising one or more capping ligands on a copper-containing core. The ink composition may be an organic solvent-based dispersion. Conventional inks may contain two types of colored material, dye or pigment, and are characterized by their main liquid, which is the vehicle for the ink. The main liquid may be water (water-based inks), or an organic solvent (solvent-based inks).

The dye or pigment based inks differ with respect to the physical nature of the colored material. Pigment is a colored material that is insoluble in the liquid, while the dye is soluble in the liquid. Each system has drawbacks: pigments tend to aggregate, and therefore, in ink-jet printing, for example, clog the nozzles in the orifice plate, or the narrow tubings in the printhead, thus preventing the jetting of the ink while printing. Dyes tend to dry, and, in ink-jet printing, for example, form a crust on the orifice plate, thus causing failure in jetting and misdirection of jets.

It is clear that the term “dye” or “pigment” is a general wording for materials, which are soluble or insoluble, respectively, in the solvents comprising the ink. Therefore, metal nanoparticles may be considered, in this context, if introduced into an ink, as pigments of metal, having a size in the nanometer range.

Conventional pigments in inks contain particles in the size range of 100-400 nm. In theory, reducing the particle size to 50 nm or less should show improved image quality and improved printhead reliability when compared to inks containing significantly larger particles.

Another aspect of the present invention is directed toward a method of printing comprising printing an ink composition comprising oxidation-resistant, ligand-capped nanoparticles, each comprising one or more capping ligands on a copper-containing core onto a substrate.

Yet another aspect of the present invention is directed toward a thin film comprising a plurality of oxidation-resistant, ligand-capped nanoparticles, each comprising one or more capping ligands on a copper-containing core operably linked together in the form of a thin film. Thin films are formed by immersion of a substrate material into a solution of nanoparticles and linker molecules. The film forms on the surface of the substrate by spontaneous sequential reactions: exchange, crosslinking, and precipitation. The thickness of the film produced by this one-step process is controlled by immersion time and concentration ratios. The film continuously grows on the immersed substrate surface until all the nanoparticles in solution are assembled into the film or the substrate is removed from the solution. The linker molecules may be nonanedithiol or diaminodecane.

A still further aspect of the present invention is directed toward a detector for volatile organic compounds comprising a sensing platform comprising the thin film of the present invention assembled on a chemiresistor device. This detector also includes a resistance measurement meter connected to a voltage source.

In a preferred embodiment, the chemiresistor device comprises interdigitated microelectrodes.

Yet another aspect of the present invention is directed toward a method of detecting volatile organic compounds including providing a detector substantially the same as described above and analyzing a sample with the detector to detect the presence of volatile organic compounds in the sample.

One aspect of the present invention couples nanostructured sensing materials with chemiresistive transducer sensing platforms (e.g., interdigitated microelectrode (IME)). See Han, L., et al., Anal. Chem., 73: 4441 (2001), which is hereby incorporated by reference in its entirety. The detection mechanism is based on the vapor-nanostructure interactions which induce changes in electronic conductivity with unique response signatures. The electronic conduction and framework affinity display electronic responses that are highly sensitive due to fine-tunability of size, shape, composition, and spatial properties, large surface area-to-volume ratio, multidentate ligating specificity, and molecularly-defined nanoporosity. See Schmid, G., Adv. Eng. Mater., 3: 737 (2001); Shipway, A., et al., Chem Phys Chem., 1:18 (2000); Zhong, C., et al., Adv. Mater., 13: 1507 (2001); Wohltjen, H., et al., Anal. Chem., 70: 2856 (1998); Han, L., et al., Anal Chem., 73: 4441 (2001); Zamborini, F., et al., J. Am. Chem. Soc., 124: 8958 (2002); Dickert, F., et al., Ber. Bunsen, Phys. Chem., 100: 1312 (1996); and Zheng, W., et al., Anal. Chem., 72: 2190 (2000), which are hereby incorporated by reference in their entirety.

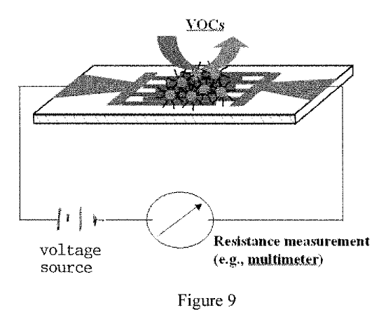

As illustrated in FIG. 9, the sensing measurement includes a sensing film and a chemiresistor device which is connected through a circuit to a resistance measurement device (e.g., a multimeter) for detecting volatile organic compounds. The sensor may detect volatile organic compounds by sensing the sorption of volatile organic compounds in the sensing film through the chemiresistor device.

The response profiles or patterns of a sensor to a certain set of volatile organic compounds are utilized for identification of the vapors.

Volatile organic compounds are emitted as gases from certain solids or liquids. Volatile organic compounds include a variety of chemicals, some of which may have short- and long-term adverse health effects. Concentrations of many volatile organic compounds are consistently higher indoors (up to ten times higher) than outdoors. Volatile organic compounds are emitted by a wide array of products numbering in the thousands. Examples include: paints and lacquers, paint strippers, cleaning supplies, pesticides, building materials and furnishings, office equipment, such as copiers and printers, correction fluids and carbonless copy paper, graphics and craft materials including glues and adhesives, permanent markers, and photographic solutions.

Organic chemicals are widely used as ingredients in household products. Paints, varnishes, and wax all contain organic solvents, as do many cleaning, disinfecting, cosmetic, degreasing, and hobby products. Fuels are made up of organic chemicals. All of these products can release organic compounds when in use and when stored. Non-limiting examples of volatile organic compounds include aliphatic compounds (e.g. alkanes, alkenes, and alkynes), aromatic compounds (e.g. benzene, toluene, pyridine, imidazole, and naphthalene), alcohols, and other high vapor pressure compounds.

### EXAMPLES

### Example 1

### Chemicals

Copper(II) acetyl acetonate (Cu(acac)₂, 98% pure) was obtained from Lancaster Oleic acid (99%) was obtained from Alfa Aesar. 1,2-hexadecanediol (90%), octyl ether (99%), oleyl amine (70%), hexane, and other common solvents used were obtained from Aldrich. Argon gas was obtained from the Matheson Tri-Gas company.

### Example 2

### Nanoparticle Preparation

Copper synthesis in organic suspension was achieved through the adaptation of a method used to synthesize FePt nanoparticles See Sun, S., et al., Science, 287: 1989 (2000), which is hereby incorporated by reference in its entirety. In the modified synthesis, copper(II) acetyl acetonate was added to octyl ether to create a 20 mM solution of copper(II). Then, 1,2-hexadecanediol was added to the solution (60 mM). The solution was heated under argon gas to a temperature of 105° C. with stirring. The solution was held at 105° C. for 10 minutes. Then, both oleic acid and oleyl amine capping agents were added to the solution to create 20 mM solutions of each. The solution was heated to higher temperatures, which was varied from 150 to 210° C. Once at the high temperature, the solution was left to react for 30 minutes. The solution was next cooled to room temperature. Finally, the reacted solution was mixed with ethanol and the particles were allowed to precipitate overnight. The supernatant was removed and the nanoparticle sediment was dried using a stream of nitrogen gas. The nanoparticles were suspended in hexane and were ready for analysis.

### Example 3

### Ultraviolet Visible Spectrometry (UV-Vis)

UV-Vis spectra were acquired with an HP 8453 spectrophotometer A quartz cell with a path-length of 1 cm was used and spectra were collected over the range of 200-1100 nm.

### Example 4

### Transmission Electron Microscopy (TEM)

TEM was performed on an Hitachi H-7000 electron microscope (100 kV). For TEM measurements, copper nanoparticle samples were suspended in hexane solution and were drop cast onto a carbon-coated copper grid followed by solvent evaporation in air at room temperature.

### Example 5

### X-Ray Powder Diffraction (XRD)

XRD data was collected on a Philips X'Pert diffractometer using Cu Kα radiation (λ=1.5418 Å). The measurements were done in reflection geometry and the diffraction (Bragg) angles 2θ were scanned at a step of 0.025°. Each data point was measured for at least 20 seconds and several scans were taken of the sample.

### Example 6

### Results and Discussion

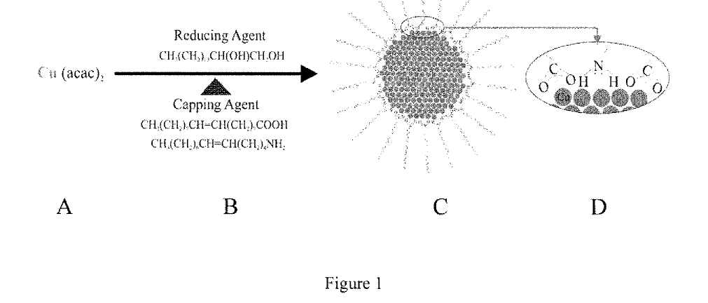

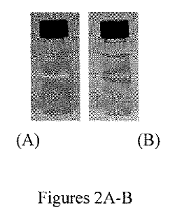

The general reaction is shown in FIG. 1 for the synthesis of copper nanoparticles of different sizes, which was accomplished by varying the reaction temperature in the range of 150-190° C. As the temperature of reaction was raised, the solutions with the resulting nanoparticles were found to become darker in color. The size evolution and shape formation, which are highly dependent on reaction temperature, will be detailed below. As a general observation, the color evolution of the reaction solution under different temperatures was found to serve as an indication for the particle size evolution. When the reaction temperature was held at 150° C., a yellow solution was observed (FIG. 2A). This color corresponded to small sized copper nanoparticles. As reaction temperature was increased, the color of the solution with the as-synthesized copper nanoparticles showed a series of color changes, ranging from light yellow, to orange, dark brown, and purple brown depending on the reaction temperature. The brown colored solution was observed for particles synthesized at 180° C. (FIG. 2B).

UV-Visible spectra of the resulting nanoparticle solutions displayed a surface plasmon (SP) resonance band at ˜600 nm, characteristic of copper nanoparticles. Copper nanoparticles synthesized by other methods were reported display an SP band at 570 nm. See Kim, Y. H., et al., Mol. Cryst. Liq. Cryst., 445: 231 (2006) and Salzemann, C., et al., Langmuir, 20: 11772-11777 (2004), which are hereby incorporated by reference in their entirety. The exact position of this band may shift depending on the individual particle properties including size, shape, solvent used, and capping agent employed. The spectrum for the as-synthesized small particles showed a rising feature at ˜440 nm. For the solution of nanoparticles synthesized at 150° C. a rising band at about 435 nm was apparent in the UV-Vis spectrum. As the particles became larger, this band shifted to higher wavelength (up to ˜600 nm). A strong SP band was observed at 591 nm for the formation of large-sized copper nanoparticles synthesized at 200° C.

The nanoparticles synthesized under different conditions were also studied to determine their solubility and relative stability. Most of the copper nanoparticles were soluble in hexane. It was observed that the well-suspended nanoparticles remained in solution without precipitating for several weeks. The precipitated particles could also be easily re-suspended. When additional oleyl amine or oleic acid was added to the nanoparticle solution, the solution was found to turn to blue, suggesting the formation of copper (II) ions. This instability appears to reflect an equilibrium shift that promotes the oxidation Cu (0) to form Cu(II)-oleyl amine or -oleic acid complexes in solution. See Chen, S., et al., J. Pys. Chem. B, 105: 8816 (2001), which is hereby incorporated by reference in its entirety. In order to determine whether the copper particles synthesized were stable under ambient conditions (˜20° C.), a small amount of the nanoparticle solution was placed in a vial and left open to the air for several weeks. There were no indications of changes in the solution color, including an unchanged SP band in the UV-Vis spectra. TEM imaging of the samples after several weeks also showed that the as-synthesized nanoparticles were stable under ambient conditions. This stability is desired, because the nanoparticles can be stored under ambient condition for long periods of time before use.

### Example 7

### Copper Nanoparticles of Different Sizes

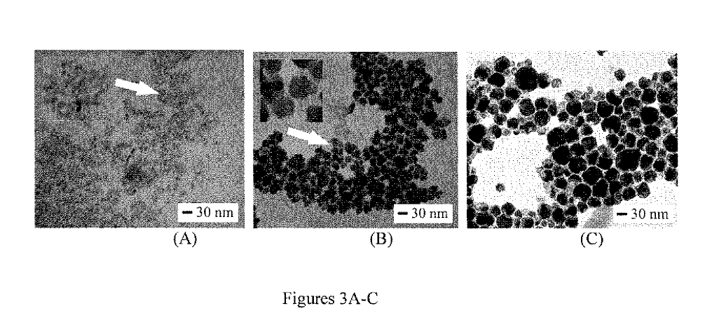

Analysis of the nanoparticles showed an increasing trend in the average size with the reaction temperature. FIGS. 3A-C shows a representative set of Transmission Electorn Microscopy (TEM) micrographs for copper nanoparticles synthesized at three different temperatures. At 150° C., the particles showed small sizes with flower-like outlines (FIG. 3A). At 160° C., the particles became larger, more spherical and showed a tendency to cluster (FIG. 3B). As the temperature was increased to 190° C., the particles became even larger, more spherical, and showed a better-defined interparticle separation (FIG. 3C).

The average sizes of the particles range from 5 to 50 nm depending on the reaction temperature, with the standard deviation of the particle sizes ranging from ±1.80 nm to ±2.5 nm. The particles synthesized at temperatures below 190° C. were highly monodispersed, with standard deviations less than 3.5 nm. When the synthesis temperature was raised above 190° C., the nanoparticles showed an increased standard deviations, e.g., 24.01±6.48 nm (190° C.), and 15.06±2.53 nm (200° C.).

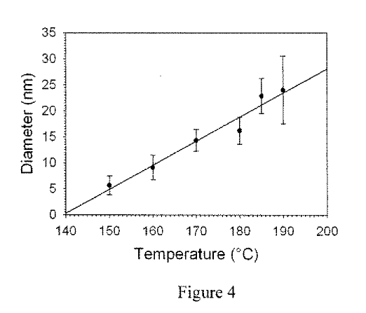

FIG. 4 shows a plot of the average particle size vs. the reaction temperature. The average size of the nanoparticles was found to increase approximately linearly with temperature. The linear regression of the data yields 0.46 nm/° C. This finding is significant, demonstrating the important role of reaction temperature in the control of the particle sizes.

A close examination of some of the large-sized particles seems to reveal subtle cluster features. This observation may hint the possibility of coalescence of smaller-sized particles, which provides some implications to understanding the mechanistic origin of the size dependence on temperature. It is known that the growth of nanoparticles is influenced by the strength of adsorption of the encapsulating ligands and the competition between the interparticle aggregation for the growth of the particles and the molecular encapsulation for the stabilization of the nanoparticles. In order for growth to occur, the desorption of an encapsulating ligand on the particle must occur, allowing a metal atom to gain access to the particle surface. The adsorption of capping molecules on the copper nanoparticles is favored at lower temperatures, thus limiting the particle growth rate. However, as the temperature is increased, the desorption of the capping ligand from the nanoparticle surface is favored, increasing the opportunities for interparticle coalescence.

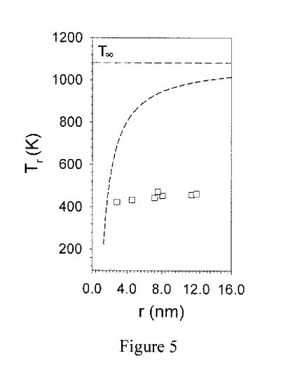

One of the important conditions for interparticle coalescence is surface melting. As demonstrated in earlier work for the size evolution of gold nanoparticles at elevated temperatures, the decrease of melting point for nano-sized particles is an important factor for interparticle coalescence. See Maye, M., et al., Langmuir, 16: 490-497 (2000), which is hereby incorporated by reference in its entirety. The decrease of melting point with reducing particle sizes can be explained by the early thermodynamic model describing melting curves for fine metal particles (see Buffat, P., et al., Phys. Rev. A, 13: 2287 (1976), which is hereby incorporated by reference in its entirety), which relates the melting point of nanoparticles to that of its bulk metal by the equation:

$$\frac{{T}_{r} - {T}_{∞}}{{T}_{∞}} = - \frac{4}{{ρ}_{s} L 2 r} [ {γ}_{s} - {{γ}_{l} ( \frac{{ρ}_{s}}{{ρ}_{l}} )}^{2 / 3} ] \qquad ( 1 )$$

where Tᵣ and T_{∞} are melting temperatures of the particle and the bulk solid, respectively, r is the radius of the particle, ρₛ and ρₗ are the density of the solid and the liquid, γₛ and γₗ are the surface energy of the solid and the liquid, and L is the heat of fusion. The theoretical model predicts a decrease of the melting point with decreasing particle size, as illustrated in FIG. 5.

The implication of this trend is that the smaller particles have a tendency of melting or partial melting at the reaction temperature. The actual temperatures used in the synthesis vs. the particle size of the products are included in FIG. 5, showing that the experimental temperatures are much smaller than the theoretical temperatures for the melting curve. For the smallest particle size, the reaction temperature was relatively closer to that in the theoretical curve, with a difference of ˜100° C. On the basis of this observation, it is believed that it is likely the surface melting of the nanoparticles which is responsible for the interparticle coalescence, leading to the size growth as the reaction temperature is increased. This temperature-controlled size growth is the first example demonstrating the important role of surface melting in the synthesis of copper nanoparticles. While the lowering of melting point is inversely proportional to the particle size (r), the surface melting temperature could be even lower (e.g., ˜140° C. for 2-nm Au). See Maye, M., et al., Langmuir, 16: 490-497 (2000), which is hereby incorporated by reference in its entirety. The relative change of the temperature is also related to the capping-dominated surface tension. Under such surface melting and surface tension effects, the driving force for coalescence of two surface-melt Cu particles is the reduction in free energy through a reduction in surface area, i.e., increase of size.

### Example 8

### Formation of Shaped Cu Nanoparticles

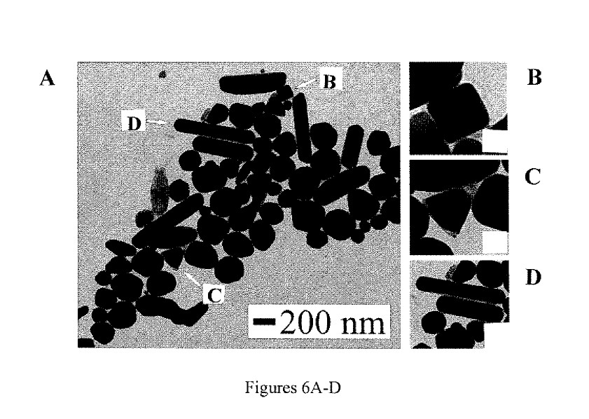

By further modifying the synthesis procedure, copper nanoparticles with significantly increased populations of shaped particles were produced. It was also found that copper nanoparticles with different shapes began to form at temperatures above 190° C. FIG. 6 shows a representative TEM image of the as-synthesized particles derived from the reaction temperature of 210° C. and a careful control of the initial heating rate in the presence of the capping agents. The shaped nanoparticles include cubes, rods, and tetrahedrons. A small percentage of spherically shaped particles were also produced. Shape formation began at 190° C., but was not prominent until 200° C., when shapes such as rods and cubes became common among the particles. In all of the samples that formed shapes, rods were the most common shape, demonstrating that, at high temperature, the formation of copper nanoparticles have a great propensity to form rods. As indicated by the enlarged views, the cubes, rods, and tetrahedrons have well-defined shapes. The cube-shaped particles feature 200 nm in size. The rod-shaped particles feature 700 nm in length and 100 nm in width, with an aspect ratio as high as ˜7. It is important to note that these shaped particles do not show any hint of the possibility of coalescence of smaller-sized particles as observed for the spherical particles described earlier, thus ruling out the simple coalescence mechanism for the shape formation. The observation of these shapes is remarkable considering the relatively small change in the synthetic temperature that was required to initiate their formation.

To understand the mechanism for the formation of the shaped nanoparticles other literature was looked to. There is a remarkable resemblance between the nanoparticle shapes synthesized using the method discussed above and those reported by others who used a method in which Cu(AOT)₂ and NaAOT is solubilized in isooctane with a controlled percentage of water. See Salzemann, C., et al., Langmuir, 20: 11772-11777 (2004), which is hereby incorporated by reference in its entirety. This forms spherical reverse micelles in which Cu(AOT)₂ is reduced by various concentrations of hydrazine. Using both synthetic methods, spheres, rods, cubes and tetrahedra were observed. According to the mechanism proposed, the formation of the rod-, cube-, and tetrahedral-shaped copper nanocrystals requires (i) the initial formation of a decahedral, cuboctohedral, and tetrahedral precursors, and (ii) the preferential adsorption of capping agents on the nanocrystal facets in order to kinetically control the growth rates of the crystal facets.

For the growth process in the synthetic method that is the focus of the present invention, it is possible that one of the capping agents favors bonding with some faces (111, 110 or 100), while the other favors another type. In this case, one of the capping agents would bond more strongly and the equilibrium process would allow some faces to grow more quickly than others. Another possibility is that both capping agents bond more strongly to one type of face and again allow some faces to grow more quickly.

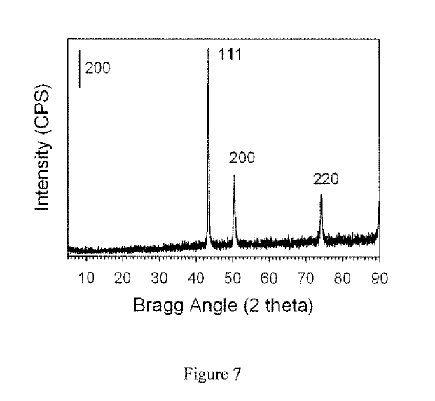

As shown in FIG. 7, the nanoparticles display high crystallinity. The diffraction peaks at 2θ=43.5, 50.6 and 74.3 can be indexed as the [111], [200] and [220] planes of copper with cubic symmetry. The pattern is very clean, with no indication of impurities such as copper oxides (CuO, Cu₂O). The results are quite consistent with those reported by others for Cu nanoparticles or nanorods prepared by different methods. See Panigrahi, S., et al., Polyhedron, 25: 1263 (2006), which is hereby incorporated by reference in its entirety.

The mechanism proposed previously for the shape formation using the reverse micelle method seems to be applicable to the synthesis of the shaped nanoparticles using the method discussed in this paper. See Salzemann, C., et al., Langmuir, 20: 11772-11777 (2004), which is hereby incorporated by reference in its entirety. The observation of several shapes in the synthesized particles is indicative of the formation of several different seed precursors. These seeds then grow, regulated by the capping agents, along different directions of the nanocrystal into particles with various shapes. A cuboctohedron seed particle can serve as a precursor. If this seed were to grow equally in all directions, it would enlarge into a roughly spherically shaped particle, however there is a difference in rate of growth along its faces. The difference in speed of growth is caused by the varying surface free energy, and thus the varying strength of capping agent adsorption. Because the capping agent adsorbs more strongly to the 100 face of the cuboctohedron nanocrystal, the 111 faces grow at a faster rate than the 100 faces. This kinetic difference leads to the formation of a cube-shaped particle, instead of a sphere. Similarly, for a decahedron seed particle the 111 faces grow at a faster rate than the 100 faces, causing a kinetically favored growth of the 111 faces into an elongated rod shaped particle. It is important to note that the final size of the particles is not solely dependent on the seed shape, but is also dependent on the total growth time of the particle.

### Example 9

### Detection of Volatile Organic Compounds

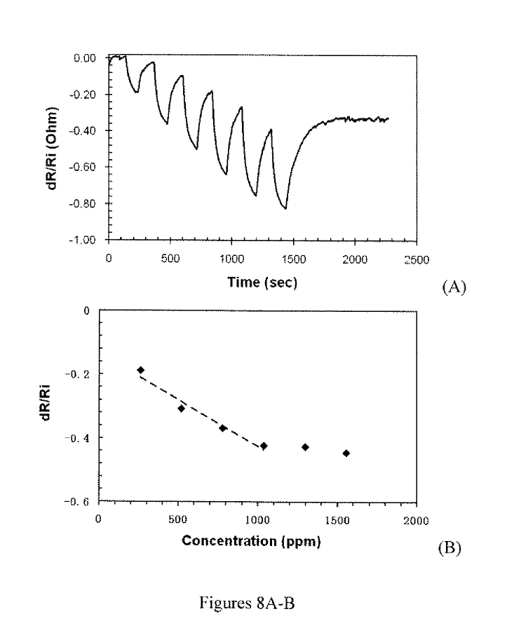

Dithiol (e.g., NDT)-mediated thin film assembly of Cu nanoparticles capped with decanethiolates applied at gap of chemiresistor device. FIGS. 8A-B show a set of the chemiresistor responses to benzene (Bz) vapor for thin film assembly of Cu nanoparticles (NDT-Cu). See FIGS. 8A-B. The response profile displays a negative sign (i.e., resistance decreases upon exposure to Bz), in contrast to the often-observed positive responses for other types of nanoparticle thin films. The response sensitivity is 3×10⁻⁴ ppm⁻¹.

The copper nanoparticle thin film was assembled on the surface of an interdigitated microelectrode (IME) device using the dithiol linking molecules. Sensor response measurements were performed using an IME device with 100 pairs of gold electrodes of 200 μm length, 10 μm width, and 5 μm spacing on a 1-mm thick glass substrate. A computer-interfaced multi-channel multimeter (Keithley, Model 2700) was used to measure the lateral resistance of the nanostructured coating on IME. All experiments were performed at room temperature, 22±1° C. N₂ gas (99.99%, Airgas) was used as reference gas and as diluent to change vapor concentration by controlling mixing ratio. The gas flow was controlled by a calibrated Aalborg mass-flow controller (AFC-2600). The flow rates of the vapor stream were varied between 3 and 99 mL/min, with N₂ added to a total of 100 mL/min. The vapor generating system consisted of a stainless steel multi-channel module linked to different vapor bubblers. The modular platform components permitted different vapor flow with minimum dead-volume and virtually no cross-contamination. The vapor concentration was controlled by a flow system bubbling dry N₂ gas through a selected vapor solvent. The IME devices were housed in a Teflon chamber with tubing connections to vapor and N₂ sources; the electrode leads were connected to the multimeter. Nitrogen was used as carrier gas. Different concentrations of vapors were generated using an impinger system. At the beginning of the experiment, the test chamber was purged with pure nitrogen for a 1 hour to ensure the absence of air and also to establish the baseline. The test chamber was purged with N₂ and the analyte vapor alternately. A series of vapor concentration was tested. The vapor concentration in the unit of ppm moles per liter was calculated from the partial vapor pressure and the mixing ratio of vapor and N₂ flows. ΔR is the difference of the maximum and minimum values of the resistance in response to vapor exposure, and Rᵢ is the initial resistance of the film. The sensitivity data were based on the relative differential resistance change, ΔR/Rᵢ, versus vapor concentration, C (ppm). The concentration given in ppm (M) in this paper, which can be converted to ppm (V) (which was often used in the literature) by multiplying a factor of 24.5, was for the convenience in thermodynamic analysis.

Although preferred embodiments have been depicted and described in detail herein, it will be apparent to those skilled in the relevant art that various modifications, additions, substitutions, and the like can be made without departing from the spirit of the invention and these are therefore considered to be within the scope of the invention as defined in the claims which follow.

What is claimed:

1. Oxidation-resistant, ligand-capped nanoparticles, said nanoparticles comprising one or more capping ligands on a copper-containing core.

2. The nanoparticles of claim 1, wherein the nanoparticles are present in a monodispersion.

3. The nanoparticles of claim 1, wherein the nanoparticles have a particle size between 2-100 nm.

4. The nanoparticles of claim 1, wherein the nanoparticles are cube-shaped.

5. The nanoparticles of claim 1, wherein the nanoparticles are spherical.

6. The nanoparticles of claim 1, wherein the nanoparticles are rod-shaped.

7. The nanoparticles of claim 1, wherein the nanoparticles are tetrahedron-shaped.

8. The nanoparticles of claim 1, wherein the one or more capping ligands is selected from the group consisting of oleic acid, oleyl amine, and mixtures thereof.

9. The nanoparticles of claim 8, wherein the one or more capping ligands is a mixture of oleic acid and oleyl amine in an oleic acid to oleyl amine ratio of from 1:99 to 99:1.

10. The nanoparticles of claim 9, wherein the one or more capping ligands are in an equimolar ratio of oleic acid to oleyl amine.

11. A method of making oxidation-resistant, ligand-capped nanoparticles comprising one or more capping ligands on a copper-containing core comprising:
providing copper-containing core precursor material;
providing a reducing agent;
treating the copper-containing core precursor material with the reducing agent;
providing one or more capping ligand precursors; and
contacting the reducing agent-treated copper-containing core precursor material and the one or more capping ligand precursors under conditions effective to form oxidation-resistant, ligand-capped nanoparticles comprising one or more capping ligands on a copper-containing core.

12. The method of claim 11, wherein the metal core precursor material is copper (II) acetyl acetonate.

13. The method of claim 11, wherein the reducing agent is 1,2 hexadecanediol.

14. The method of claim 11, wherein the one or more capping ligands is selected from the group consisting of oleic acid, oleyl amine, and mixtures thereof.

15. The method of claim 14, wherein the one or more capping ligands is a mixture of oleic acid and olelyl amine in a oleic acid to oleyl amine ratio of from 1:99 to 99:1.

16. The method of claim 15, wherein the one or more capping ligands is in an equimolar ratio of oleic acid to oleyl amine.

17. The method of claim 11, wherein the nanoparticles are present in the form of a monodispersion.

18. The method of claim 11, wherein the nanoparticles have a particle size between 2-55 nm.

19. The method of claim 11, wherein the nanoparticles are cube-shaped.

20. The method of claim 11, wherein the nanoparticles are spherical.

21. The method of claim 11, wherein the nanoparticles are rod-shaped.

22. The method of claim 11, wherein the nanoparticles are tetrahedron-shaped.

23. The method of claim 11, wherein said treating comprises heating the copper-containing core precursor and the reducing agent at a first temperature to produce a heated reaction mixture and said contacting comprises heating the reaction mixture and the one or more capping ligand precursors to a second temperature under conditions effective to form the oxidation resistant, ligand-capped nanoparticles comprising one or more capping ligands on a copper-containing core.

24. The method of claim 23, wherein said first temperature is 100 to 110° C.

25. The method of claim 23, wherein said second temperature is 145 to 210° C.

26. The method of claim 25, wherein said second temperature is 145 to 155° C.

27. The method of claim 26, wherein the nanoparticles are 3-7 nm in diameter.

28. The method of claim 25, wherein said second temperature is 150 to 165° C.

29. The method of claim 28, wherein the nanoparticles are 6-12 nm in diameter.

30. The method of claim 25, wherein said second temperature is 165 to 175° C.

31. The method of claim 30, wherein the nanoparticles are 12-17 nm in diameter.

32. The method of claim 25, wherein said second temperature is 176 to 185° C.

33. The method of claim 32, wherein the nanoparticles are 13-18 nm in diameter.

34. The method of claim 25, wherein said second temperature is 186 to 210° C.

35. The method of claim 34, wherein the nanoparticles are 16-32 nm in diameter.

36. An ink composition comprising the oxidation-resistant, ligand-capped nanoparticles of claim 1.

37. The ink composition of claim 36, wherein the ink composition is an organic solvent-based dispersion.

38. A method of printing comprising printing an ink comprising the ink of claim 36 onto a substrate.

39. A thin film comprising a plurality of the oxidation-resistant, ligand-capped nanoparticles of claim 1 operably linked together in the form of a thin film.

40. A detector for volatile organic compounds comprising:
a sensing platform comprising the thin film of claim 39 assembled on a chemiresistor device; and
a resistance measurement meter operably linked to a voltage source and the sensing platform.

41. A method of detecting volatile organic compounds, said method comprising:
providing the detector of claim 40; and
analyzing a sample with the detector to detect the presence of volatile organic compounds in the sample.
